(19) United States
(12) Patent Application Publication
(10) Pub. No.: US 2008/0247214 A1
(43) Pub. Date: Oct. 9, 2008

(54) INTEGRATED MEMORY

(76) Inventor: Klaus Ufert, Unterschleissheim (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/695,677

(22) Filed: Apr. 3, 2007

(51) Int. Cl. G11C 11/00; H01L 45/00

(52) U.S. Cl. 365/148; 257/4; 438/104; 257/E45.001

(57) ABSTRACT

In one aspect, a resistive memory device may be implemented in an embedded system. A resistive memory may comprise a resistive switchable medium that may be electrically connected to a first and a second electrode. In one aspect the first and the second electrode may comprise a via conductor and an interconnection line of an embedded structure.

### TECHNICAL FIELD

This description is directed generally to an integration of a memory cell.

Details of one or more implementations are set forth in the accompanying exemplary drawings and exemplary description below. Other features will be apparent from the description and drawings, and from the claims.

### BRIEF DESCRIPTION OF THE DRAWINGS

FIG. 1 shows a schematic of an exemplary embedded system;

FIG. 2 shows a schematic cross section of an exemplary interconnection structure;

FIG. 3 shows a schematic cross section of another exemplary interconnection structure;

FIG. 4 shows a perspective schematic of an exemplary memory device;

FIG. 5A to 5H show an exemplary method of fabricating a device; and

FIG. 6A to 6F show another exemplary method of fabricating a device.

### DETAILED DESCRIPTION

An embedded structure in which a resistive memory device may be implemented, may, for example, comprise a multilevel interconnection structure including two or more levels of circuit layers and/or wiring layers. This may allow a high density of active components, such as transistors, to be integrated in the same device, such as a chip.

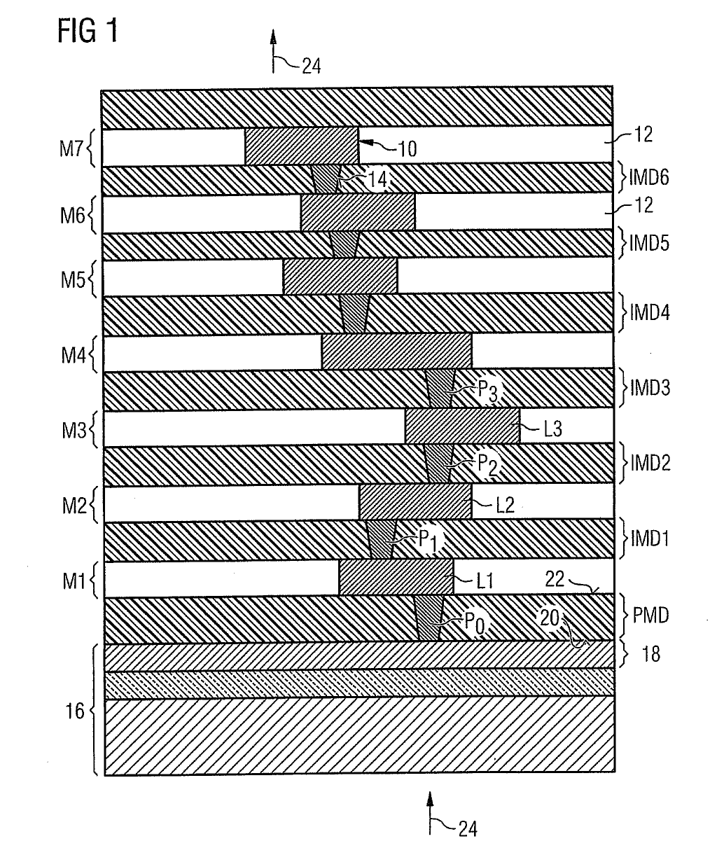

FIG. 1 shows an example of an embedded system. A multilevel-interconnect structure according to one aspect may comprise two or more structured metallization layers M1, M2, etc. that may be physically separated by inter-metal dielectric layers IMD1, IMD2, etc. Neighboring levels of structured metallization layers M1, M2, etc. may be at least partly electrically interconnected through metal plugs P1, P2, etc. (also known as vias or via conductors) formed in the inter-metal dielectric layer therebetween. In one aspect, the metallization layers may be structured such that they may comprise at least one laterally extending conduction line or interconnection line L1, L2, etc., which may be arranged in trenches 10 formed in insulating material, such as a dielectric trench isolation material 12 exemplarily shown in FIG. 1. The dielectric trench isolation material 12 my be comprised in the structured metallization layers M1, M2, etc. and may be formed as dielectric trench isolation layers 12 when forming the metallization layers, for example.

A method of fabricating a multilevel-interconnect structure may comprise a step of forming a structured first-level metallization layer M1, a step of forming an inter-metal dielectric layer IMD1 over the structured first-level metallization layer M1, a step of forming a metal plug P1 at a predetermined location in the inter-metal dielectric layer IMD1, which is electrically connecting to the structured first-level metallization layer M1, and a step of forming a structured second-level metallization layer M2 over the inter-metal dielectric layer IMD1. In one example, further levels of structured metallization layers M3, M4, etc. may be formed over the structured second-level metallization layer M2.

In one example, the metal plug P1 and the overlying structured metallization layer M2 may be formed separately through different steps. In another example, such as the so-called dual damascene technology, at least some of the metal plugs P1, P2, etc. and the respective overlying structured metallization layer M2, M3, etc. and, in particular, the interconnection lines L1, L2, etc. comprised in the metallization layers, may be formed together in one deposition step. A horizontally or laterally extending trench 10 and a vertically extending via hole 14 may be formed together at the same layer-level, for example, and then a metal may be deposited into the trench 10 and the via hole 14, with the deposited metal in the via hole 14 serving as the metal plug P1, P2, etc. and the deposited metal in the trench 10 serving as the overlying structured metallization layer M1, M2, etc., and particularly, as the interconnection line L1, L2, etc. The combined structure of the metal plug P1, P2, etc. and the overlying structured metallization layer M2, M3, etc. or interconnection line L1, L2, etc. may be referred to as a dual-damascene structure.

A device may, for example, comprise planarized multilevel structures including alternating layers of insulating materials which may, for example, support dual damascene and/or single damascene metal interconnections, such as the inter-metal dielectric layers IMD and the dielectric trench isolation layers 12 which may be comprised as the insulation parts of the structured metallization layers M1, M2, etc. Exemplary structures may include alternating layers of insulating films, for example low-k dielectric films, with alternating chemical-mechanical hardmask layers, for example silicon nitride and/or high density plasma oxide. Damascene metal may comprise, for example, copper.

In one aspect, such as the example shown in FIG. 1, a device may comprise a semiconductor substrate 16 having a semiconductor operation layer 18 with a substrate surface or operation layer surface 20. A pre-metal dielectric layer PMD may be arranged at the operation layer surface 20 (or substrate surface) and may separate the structured first-level metallization layer M1 from the substrate 16 and, particularly, from the semiconductor operation layer 18. An upper surface of the pre-metal dielectric layer PMD, which, in one aspect, may be referred to as an interconnection surface 22 or a first interconnection surface, may be planar, for example.

In one aspect the substrate may have a substrate normal direction 24 as exemplarily indicated in FIG. 1. Directions parallel to the substrate normal direction 24 may be referred to as “vertical”, while directions perpendicular to the substrate normal direction 24 may be referred to as “horizontal” or “lateral” throughout this description. In this sense the semiconductor operation layer 18 and/or the pre-metal dielectric layer PMD and/or at least one of the inter-metal dielectric layers IMD1, IMD2, etc. and/or at least one of the structured metallization layers M1, M2, etc. may extend in substantially horizontal direction, for example, i.e. in one aspect they may be substantially parallel to each other and to the horizontal directions.

The semiconductor operation layer 18 may comprise active components, such as components of a field effect transistor, for example. The active components may comprise contact regions, such as a source region and/or a drain region and/or a gate structure including a gate contact of a field effect transistor.

In one aspect, embedded systems may comprise a combination of different active and/or passive components, such as memories and/or processing units and/or input/output interfaces, for example. In one aspect, a device may comprise at least one resistive memory cell that may be based on a bi-stabile transition of the resistance in a transition metal oxide or a transition metal chalcogenide, for example.

In one aspect, a memory device may comprise a vertically extending via conductor, a lateral interconnection line, and a storage region interposed between the via conductor and the interconnection line. The memory device may, for example, comprise a vertical-interconnection layer comprising a via hole which extends through the vertical-interconnection layer and which is at least partly filled with said via conductor; and a lateral-interconnection layer arranged at the vertical-interconnection layer and comprising at least one lateral trench which is in communication with the via hole and which is at least partly filled with said interconnection line. In one aspect, the storage region may comprise a resistive switchable medium.

The storage region may be arranged in the via hole, for example. In another example, the storage region may be arranged in the trench.

In one aspect an interconnection structure may comprise at least one interconnection layer sequence. The interconnection layer sequence may, for example, comprise a dielectric layer, such as the pre-metal dielectric layer PMD or an inter-metal dielectric layer IMD, exemplarily shown in FIG. 1. The dielectric layer may have a first sequence connection surface and a sequence intermediate surface. The interconnection layer sequence may further comprise an interconnection layer, such as the structured metallization layers M1, M2, etc. exemplarily shown in FIG. 1. In one aspect the interconnection layer may be arranged at the sequence intermediate surface and may, for example comprise a second sequence connection surface.

In one aspect, in the interconnection layer sequence an interconnection channel may be formed which may comprise a via hole formed in the dielectric layer, and a trench formed in the interconnection layer, where the trench may be in communication with the via hole. The via hole may, for example, extending from a first via opening in the first sequence connection surface to a second via opening in the sequence intermediate surface. In one aspect, a resistive switchable medium may be arranged in the interconnection channel at the second via opening, for example. It may form an electrical interconnection between a via conductor arranged in the via hole and an interconnection line arrange in the trench. In this aspect, the via conductor may form a vertical component of an interconnection, which may be substantially parallel to the substrate normal direction 24.

The interconnection line in the trench, on the other hand may form a vertical component of an interconnection in an embedded system, for example. An interconnection structure according to this aspect may provide an efficient implementation of a non-volatile memory device in an embedded system.

In one aspect, the resistive switchable medium may be at least partly arranged in the trench. Alternatively or additionally, the resistive switchable medium may be at least partly arranged in the via hole.

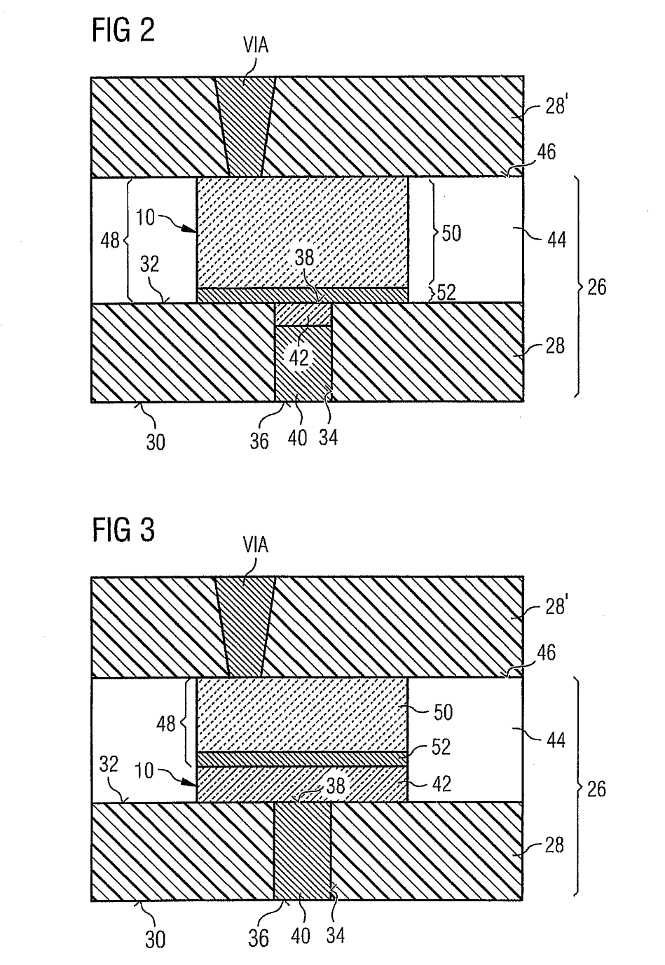

In another aspect, an integrated circuit may comprise at least one layer sequence with a dielectric layer having a via hole formed therein and with an interconnection layer having a trench formed therein. The trench may be in communication with the via hole such as to form an interconnection channel together with the via hole. A resistive switchable medium may be arranged in said interconnection channel, where the resistive switchable medium forms an electrical interconnection between a via conductor arranged in the via hole and an interconnection line arranged in the trench. In one example the via conductor extends vertically and the interconnection line extends laterally. In one example, the resistive switchable medium may be arranged in the via hole. In another example, the resistive switchable medium may be arranged in the trench. In yet another example, the resistive switchable medium may be partly arranged in the via hole and in the trench. The integrated circuit may be designed as a memory device or a memory module having at least one memory cell that comprises said resistive switchable medium as a storage region. The integrated circuit may be implemented in an embedded system as exemplarily described in connection with FIG. 1. In another example, the integrated circuit may be implemented in one or more of the structures described in connection with FIGS. 2 and 3 in the following.

FIG. 2 shows an exemplary interconnection structure sequence, which comprises an interconnection layer sequence 26. This exemplary interconnection layer sequence 26 comprises a dielectric layer 28, which may be embodied as a pre-metal dielectric layer or an inter-metal dielectric layer for example. In the shown example, the dielectric layer comprises a first sequence connection surface 30 and a sequence intermediate surface 32. In one aspect of an exemplary memory device, the first sequence connection surface 30 may be implemented or represented by an operation layer surface 20 of a semiconductor substrate 16 as exemplarily shown in FIG. 1. The sequence intermediate surface 32 may be implemented or represented by an interconnection surface 22 exemplarily shown in FIG. 1.

As shown in the example of FIG. 2, the dielectric layer 28 may comprise a via hole 34 that extends from a first via opening 36 in the first sequence connection surface 30 to a second via opening 38 in the sequence intermediate surface 32. The via hole 34 is at least partly filled with a via conductor 40. The via conductor 40 may comprise electrically conductive material, such as metal, for example. In one example, the via conductor 40 may comprise a tungsten plug. The dielectric layer 28 may comprise dielectric material such as doped or undoped silicon dioxide, for example. A thickness of the dielectric layer in substrate normal direction may be between 350 nm and 550 nm, for example.

In one aspect, a resistive storage region 42 comprising a resistive switchable medium may be arranged at the sequence intermediate surface 32. In the example of FIG. 2, the resistive storage region 42 is arranged in the via hole 34 directly adjacent to the via conductor 40 which may form a bottom contact of an integrated memory cell. In one example, the via conductor 40 may comprise a tungsten plug, while the storage region 42 may comprise tungsten oxide. A cross sectional extension in a direction perpendicular to the substrate normal direction or a diameter of the tungsten plug by be between 20 nm and 100 nm, for example.

In the exemplary interconnection structure of FIG. 2, the interconnection layer sequence 26 further comprises an interconnection layer 44 arranged at the sequence intermediate surface 32. The interconnection layer 44 comprises a second sequence connection surface 46 representing a surface of the interconnection layer sequence 26 opposite to the first sequence connection layer. In one aspect, further interconnection layer sequences may be arranged at the second sequence connection surface 46 to form a multi-layer embedded system similar to the example shown in FIG. 1. FIG. 2 indicates this possibility by showing a further dielectric layer 28′, which may represent part of a further interconnection layer sequence arranged at the second sequence connection surface 46.

A thickness of the interconnection layer in substrate normal direction may be between 150 nm and 300 nm, for example. Nevertheless, also other layer thicknesses may be applied for the dielectric layer and the interconnection layer.

The interconnection layer 44, as shown in FIG. 2, comprises a trench 10, which may be at least partly filled with electrically conductive material forming an interconnection line 48, similar or analogous to the exemplary interconnection lines L shown in FIG. 1, for example. In the example of FIG. 2, the interconnection line 48 comprises a top contact 50 and a seed layer 52 arranged between the top contact 50 and the resistive storage region 42. The resistive storage region 42 together with the via conductor 40 and the interconnection line 48, therefore, may form a non-volatile resistive memory cell.

In one aspect, the interconnection line 48 may provide lateral electrical conductance within the interconnection layer 44, while the via conductor 40 may provide vertical electrical conductance through the dielectric layer 28 or between different interconnection layers.

In one aspect, an exemplary resistive memory cell may be reversibly switched between an electrically high resistive state and an electrically low resistive state. An electrical resistance ratio of the high resistive state with respect to the low resistive state may, for example, be at least 10. In another example, the ratio may be at least 100. In one aspect a resistive memory cell may be rapidly switchable, for example in the region of the switching times of conventional DRAM/SRAM memory cells or not more than a factor of 10 slower, for example. A resistive memory cell may comprise two electrode means and a switchable medium extending between the two electrode means, i.e. the switchable medium may connect one of the electrode means with the other one. In one example, the switchable medium, such as the resistive storage region 42, may be arranged between the two electrode means, such as the via conductor 40 and the interconnection line 48, for example.

In one aspect, the switchable medium may exhibit two different stable states, i.e. one high resistive state and one low resistive state, between which the switchable medium may be switched reversibly. In another example, the switchable medium may exhibit more than two stable states. Accordingly, the switchable medium may exhibit at least a high resistive state, a low resistive state and an intermediate resistive state, for example.

In one aspect a device comprising a resistive memory cell may be implemented as a non-volatile memory device, where each of the stable resistive states may represent a separate non-volatile storage status of the memory device. Reading the stored information may be achieved by determining the resistance of the switchable medium without changing its resistive status, i.e. without deleting the information stored therein, for example.

In one aspect, the switchable medium may comprise a transition metal (TM) material which is also comprised in at least one of the electrode means contacting the switchable medium or which constitutes at least one of said electrode means. For example, the switchable medium may comprise tungsten oxide, while at least one of the electrodes also comprises tungsten. In another example, the switchable medium may comprise copper sulfide and/or copper oxide, while at least one of the electrodes comprises copper.

When applying a sufficiently intense current or voltage pulse to a transition metal oxide, for example, via electrode means, at least some of the metal-oxide bonds of the transition metal oxide may break due to the electric field caused by an applied voltage pulse and/or due to a heating caused by a current flow in the medium. Heating may, for example, occur locally. Broken metal-oxide bonds may be replaced by metal-metal bonds, for example. Due to a higher electrical conductivity of the metal-metal bonds as compared to the metal-oxide bonds, the resistivity of the medium decreased through the breakage of metal-oxide bonds and the formation of metal-metal bonds, for example. Accordingly, heating of the material through a current pulse or the electrical field caused by an applied voltage may, at least locally, decrease unless a more intense current or voltage pulse is applied.

This state may represent a non-volatile low resistivity state, or an “ON” state of the resistive memory cell, while the state having less metal-metal bonds and more metal-oxide bonds may be regarded a non-volatile high resistivity state, or an “OFF” state of the resistive memory cell. A current or voltage pulse bringing the switching element from the “OFF” state to the “ON” state, as exemplarily described above, may be regarded as a “SET” pulse.

In one aspect in a low resistivity state the switchable medium may comprise an electrically conductive filament extending at least partly between the at least two electrode means. When starting from a low resistivity state, i.e. an “ON” state, and applying a current or voltage pulse having sufficient energy, an electrically conductive filament may be electrically or thermally destroyed and the switchable medium may return to its initial high resistivity state, i.e. an “OFF” state of the resistive memory cell. Such a current or voltage pulse may be regarded as a “RESET” pulse. In one aspect, the “SET” pulse and/or the “RESET” pulse may be applied in both directions, i.e. with either positive or negative polarity. For reading the stored data, a positive and/or negative read voltage V0 may be applied that is smaller than a set voltage and/or a reset voltage.

In another example, analogous processes also occur in other transition metal chalcogenides, such as copper sulfide, for example.

In one aspect, a method of integrating a storage medium in an embedded system may comprise creating a via conductor 40 extending vertically through a dielectric layer 28, arranging a resistive switchable medium 42 at one end of the via conductor 40, and arranging a laterally extending interconnection line 48 at the resistive switchable medium 42.

In a further aspect, a method of integrating a storage medium, such as the resistive storage region 42 in an embedded system may comprise a step of forming the via hole 34 in the dielectric layer 28. The method may, for example, comprise a step of filling the via hole 34 with a transition metal plug, such as a tungsten plug 40. In another aspect the method may comprise a step of implanting oxygen in at least part of the transition metal plug 40 next to the interconnection surface 32 of the dielectric layer 28. This implantation may be achieved by oxygen ion implantation with an ion energy of about 50 keV, for example, and with an exemplary density of 5·10¹⁵ cm⁻². Oxygen ion implantation may allow a highly reproducible and precise control of the degree of oxidation. Oxygen ions may be implanted to a depth of about 10 nm to about 100 nm, for example. In one example, the oxygen may be implanted to a depth of about 50 nm. The thickness of the tungsten oxide region, therefore, may be at about 50 nm, for example.

Subsequently, the tungsten plug may be annealed in inert gas atmosphere. This may lead to the formation of tungsten oxide as a resistive switching medium, for example. During the implantation process the surface apart from the via opening may be protected by a silicon nitride mask which is deposited via low pressure chemical vapor deposition (LPCVD), structured by reactive ion etching and removed after implantation via hot phosphoric acid, for example.

In a further aspect, the method may comprise arranging the interconnection line 48 at the interconnection surface 32 of the dielectric layer 28. The interconnection line 48 may comprise copper. In one aspect, the copper seed layer 52 may be deposited with a thickness of about 5 nm, for example. Depositing the seed layer 52 may be achieved by DC magnetron sputtering from a copper target at a pressure of about 5·10⁻³ mbar. The power density on the target may be about 1 to 1.5 W/cm². Argon may serve as the sputter gas. After the deposition of the seed layer 52, the copper top contact 50 may be deposited by electro-plating, for example.

FIG. 3 shows an interconnection structure according to another exemplary aspect. As already described with reference to FIG. 2, the interconnection layer sequence 26 may comprise the dielectric layer 28 and the interconnection layer 44. Analogous features as in the previously describe example are indicated with the same reference numerals in FIG. 2 and FIG. 3. Accordingly, for a more detailed description of these features, reference is made to the description above.

In the example shown in FIG. 3, the via conductor 40 extends within the via hole 34 from the first via opening 36 to the second via opening 38 through the complete dielectric layer 28. In this example, the resistive storage region 42 is arranged at the sequence intermediate surface 32 within the trench 10 of the interconnection layer 44. At the second via opening 38 the resistive storage region 42 may be electrically connected to the via conductor 40. On the opposite surface of the resistive storage region, i.e. the upper surface according to the orientation in FIG. 3, the resistive storage region 42 may be electrically connected to the interconnection line. Accordingly, the resistive storage region 42 may, together with the via conductor 40 and the interconnection line 48, form a non-volatile resistive memory element integrated in an interconnection layer sequence.

In one aspect, the resistive storage region 42 may comprise copper oxide as a resistive switchable medium, for example. In another aspect, the resistive storage region 42 may comprise copper sulfide, such as Cu₂S, as a resistive switchable medium, for example. In one aspect, a method of integrating a memory cell in an embedded system may be implemented in a Cu-dual-damascene process.

In one aspect, the resistive storage region 42 may be arrange at the sequence intermediate surface 32 by RF magnetron sputtering from a copper sulfide compound target, such as Cu₂S, for example. The pressure may be set to about 5·10⁻³ mbar and the power density at the target may be at about 2 to 2.5 W/cm². Argon may be used as a sputter gas, for example. The thickness of the resistive storage region 42 parallel to the substrate normal direction may be at about 10 nm to 100 nm, for example. In one example, the thickness is about 50 nm. The interconnection line may be fabricated as indicated with reference to FIG. 2, for example.

In one aspect, a method of integrating a resistive storage medium in an embedded system may comprise a step of forming a via hole 34 in a dielectric layer 28. The method may, for example, comprise a step of filling the via hole 34 with a via conductor 40. In one aspect, the method may comprise a step of arranging a resistive switchable medium 42 at an interconnection surface 32 of the dielectric layer 28 such as to electrically contact the via conductor 40. Further, in one aspect, a method of integrating a resistive storage medium in an embedded system may comprise at least partly covering the resistive switchable medium 42 with an interconnection line 48.

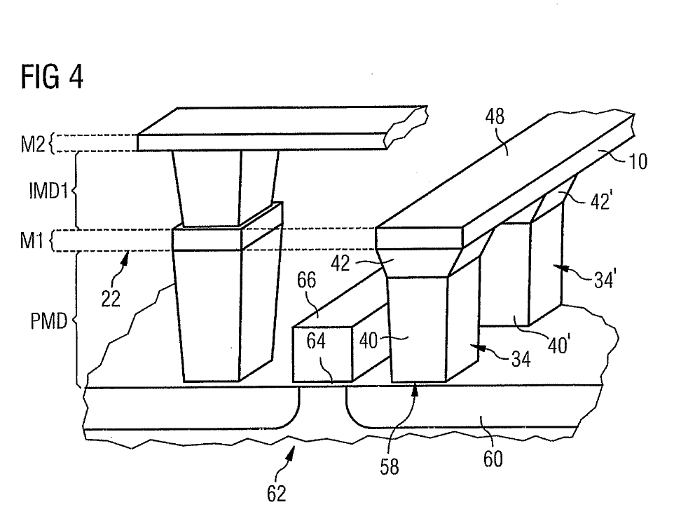

FIG. 4 shows an exemplary implementation of an interconnection structure representing a resistive memory device according to an exemplary aspect described in the following.

In one aspect, a resistive memory device may comprise a semiconductor operation layer 54 having an operation layer surface 56 with at least one contact area 58. A pre-metal dielectric layer PMD, which may be formed by the dielectric layer 28 described in connection with FIG. 2 or FIG. 3, for example, may be arranged at the operation layer surface 56 of the semiconductor operation layer 54. The pre-metal dielectric layer PMD may comprise the interconnection surface 22, which may be formed by a sequence intermediate surface 32 as described in connection with FIG. 2 or FIG. 3, for example. The via hole 34 which extends through the pre-metal dielectric layer PMD from a via opening in the interconnection surface 22 to the contact area 58. The via hole 34 may be filled with the via conductor 40, such as metal plugs P1, P2, etc. shown in FIG. 1, for example.

A structured metallization layer M1, which, in one aspect, may be identified with the structured metallization layer M1 describe for FIG. 1, for example, or which may be formed by the interconnection layer 44 described in connection with FIG. 2 or FIG. 3, for example, may be arranged at the interconnection surface 22 of the pre-metal dielectric layer PMD. This exemplary structured first-level metallization layer M1 may comprise at least one trench 10, which is in communication with the via hole 34 and which is at least partly filled with the electrically conductive interconnection line 48.

A first resistive storage region 42 comprising a resistive switchable medium may be arranged at the interconnection surface between the via conductor 40 and the interconnection line 48. In another aspect the resistive switchable medium may be electrically connected to the via conductor 40 and to the interconnection line 48.

Accordingly, FIG. 4 demonstrates one example of an implementation of a memory device of one aspect according to which a memory device may comprise a vertically extending via conductor 40, a lateral interconnection line 48, and a storage region 42 interposed between the via conductor and the interconnection line. The memory device may, for example, comprise a vertical-interconnection layer, such as the pre-metal dielectric layer PMD or an inter-metal dielectric layer, for example, comprising the via hole 34 which extends through the vertical-interconnection layer and which is at least partly filled with said via conductor 40; and a lateral-interconnection layer M1 arranged at the vertical-interconnection layer and comprising at least one lateral trench 10 which is in communication with the via hole 34 and which is at least partly filled with said interconnection line 48. In one aspect, the storage region 42 may comprise a resistive switchable medium. The storage region may be arranged in the via hole 34, for example. In another example, the storage region may be arranged in the trench 10.

The contact area 58 may be a contact area of a source/drain region 60 of a select transistor 62 arranged in the semiconductor operation layer 54 and the via conductor 40 may be electrically connected to said source/drain region 60 at the contact area 58.

In the example shown, in FIG. 4, the interconnection line 48 extends laterally within the structured metallization layer M1 and a plurality of resistive storage regions 42, 42′ are directly electrically connected to the same interconnection line 48. In this embodiment, the interconnection line 48 may be applied as a common ground for the plurality of memory cells represented by the resistive storage regions 42, 42′, for example. Each resistive storage region 42, 42′ may be connected via a separate via connector to a separate select transistor.

In one example, the semiconductor operation layer 54 may comprise a plurality of select transistors 62 arranged in at least one array comprising rows and columns. Gate contacts 64 of select transistors 62 within the same row may be electrically connected to each other through a common word line 66. The pre-metal dielectric layer PMD may comprise a plurality of via holes 34, 34′ substantially arranged in said array or in accordance with said array and each via hole 34, 34′ may be at least partly filled with a via conductor 40, 40′ being electrically connected to a source/drain region 60 of one of the plurality of select transistors 62.

In another example, the structured metallization layer M1 may comprise a plurality of substantially parallel trenches 10 extending along the columns of said array, wherein each trench communicates with a plurality of via holes within the same column and is at least partly filled with an electrically conductive bit line. The resistive memory device may comprise a plurality of resistive storage regions, wherein each of the storage regions is arranged at a via opening between the respective via conductor and a bit line and is electrically connected to the respective via conductor and to said bit line.

In one aspect, a method of fabricating a resistive memory device may comprise a step of arranging on the substrate surface 56 having at least one contact area 58 a pre-metal dielectric layer PMD having an interconnection surface 22. The method may comprise the step of forming the via hole 34 extending in the pre-metal dielectric PMD from the via opening in the interconnection surface 22 to the contact area 58. In one aspect, the method may comprise a step of filling the via hole 34 at least partly with the via conductor 40. The method may comprise the step of arranging at least at the via opening in the interconnection surface 22 the resistive switchable medium 42 such that the resistive switchable medium 42 electrically connects to the via conductor 40. In one aspect, the method may comprise a step of arranging at the interconnection surface 22 the structured metallization layer M1 comprising at least one interconnection line 48 that electrically connects the resistive switchable medium 42.

In one example, the step of forming the via hole 34 may comprise a step of depositing on the interconnection surface 22 an etch mask defining an etch opening at the position of the via opening. The step of forming the via hole 34 may, for example comprise the step of isotropically etching the pre-metal dielectric layer at the via opening to a first etch depth. In one aspect the step of forming the via hole 34 may comprise the step of anisotropically etching the pre-metal dielectric layer to extend the via hole to the contact area. This process sequence may result in a widening of the cross section of the via hole and/or the via conductor and or the resistive storage region towards the interconnection surface.

In one aspect, filling the via hole may comprise filling the via hole at least partly with a tungsten plug, and wherein the step of arranging the resistive switchable medium comprises a process of oxygen ion implantation into at least part of the tungsten plug.

In one aspect, the via hole 34 may be filled with the via conductor 40 up to the via opening in the interconnection surface 22. The method of fabricating a resistive memory device may comprise a step of arranging at the interconnection surface 22 a dielectric trench isolation layer defining at least one trench that communicates with the via opening. In one example, the step of arranging the resistive switchable medium 42 may comprise depositing the resistive switchable medium 42 at least at the via opening in the trench 10. The step of arranging the structured metallization layer M1 may, for example, comprise depositing electrically conductive material at least in the trench 10 to from the at least one interconnection line 48.

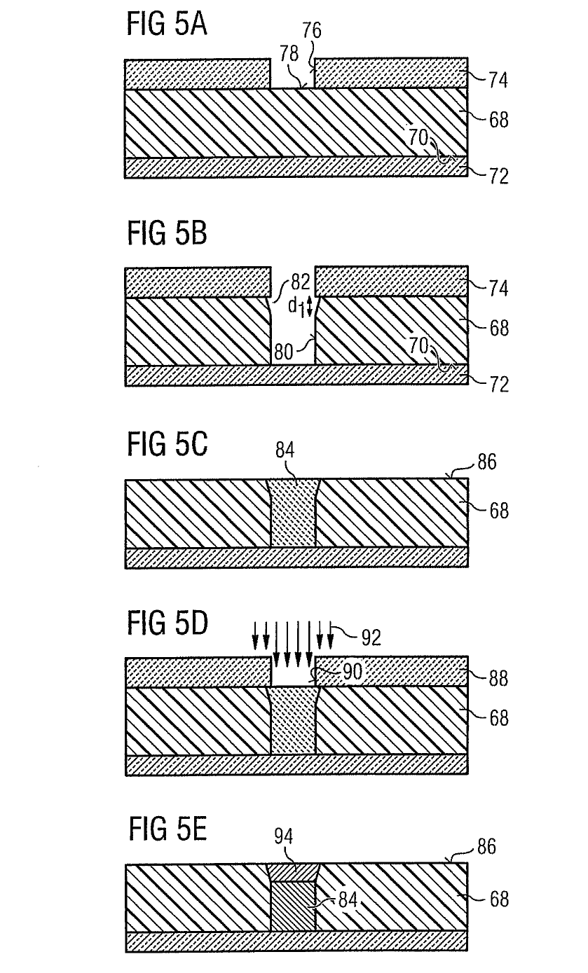

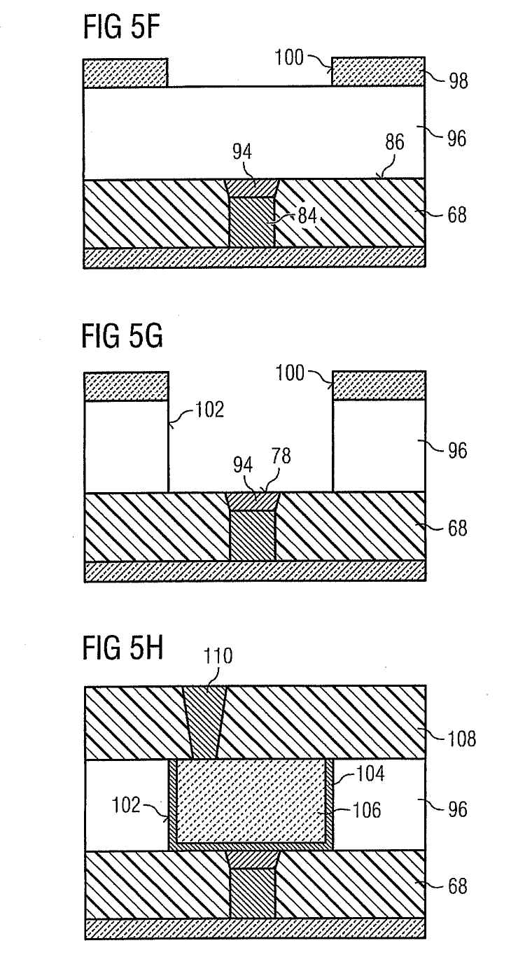

In a further aspect, an exemplary method of fabricating a memory device is described with reference to FIGS. 5A to 5H. Accordingly the method may comprise creating a via conductor extending vertically through a dielectric layer. As shown in FIG. 5A, a dielectric layer 68, such as a pre-metal dielectric layer (PMD) or an inter-metal dielectric layer (IMD) or a dielectric layer 28 as described above, for example, may be provided on a process surface 70, such as a substrate surface or an interconnection surface or the first sequence connection surface 30 described above, for example, of a contact region 72, such as a source/drain region of a transistor structure or an interconnection line, for example. A via structuring mask 74 may be deposited on the dielectric layer 68 and an etch window 76 may be opened in the via structuring mask 74 applying lithographic techniques, for example, at a position of a via opening 78, such as the second via opening 38 of the above described example, to be formed in a surface of the dielectric layer 68.

As shown in FIG. 5B, creating the via conductor may comprise forming a via hole 80 in the dielectric layer 68. In one example, the via hole 80 may be formed by etching the dielectric layer 68 in a region below the etch window 76. In a particular example, forming the via hole 80 may comprise a first etching step of isotropically etching the dielectric layer 68 at the via opening to a first etch depth d₁ and a second etching step of anisotropically etching the dielectric layer 68 to extend the via hole 80 to the contact region 72. This process sequence may result in a widened portion 82 of the via hole 80. The method, however, is not limited to a two-stage etching process. In another example, not explicitly shown in FIG. 5, formation of the via hole 80 may be performed with a single etching step, such as an anisotropic etching step, for example.

Moreover, as shown in FIG. 5C, creating the via conductor may comprise filling the via hole 80 with a metal plug 84, such as a transition metal plug, for example. This step may, for example, be performed by depositing tungsten (W). Excess metal may be removed in a step of chemical-mechanical polishing (CMP). In one example, in the step of chemical-mechanical polishing also the via structuring mask 74 is removed together with the excess metal material. In another example, the via structuring mask 74 is removed before the deposition of metal. In the example shown in FIG. 5C, chemical-mechanical polishing may lay open the planar surface 86 of the dielectric layer 68. The metal plug 84 extends through the dielectric layer 68 from the contact region 72 to the via opening 78 in the surface 86 of the dielectric layer 68.

In a further exemplary step, as shown in FIG. 5D, a lithographic hard mask 88, such as a silicon nitride mask, for example, may be deposited on the surface 86 of the dielectric layer 68 and an implantation window 90 may be opened in the lithographic hard mask 88. The implantation window 90 may be structured by reactive ion etching, for example. In a next exemplary step, ion implantation 92 may be applied to the device. In one aspect, oxygen ion implantation may be applied at an exemplary ion energy of about 50 keV and an exemplary density of 5·10¹⁵ cm⁻². The surface apart from the via opening 78 is protected by the lithographic hard mask 88 during ion implantation. In one example, oxygen ions may be implanted to a depth similar to the first etch depth d₁, thereby forming tungsten oxide in the widened portion 82 of the metal plug 84. Subsequently, the device, and particularly the metal plug 84, may be annealed in inert gas atmosphere. This may lead to the formation of a resistive switching medium 94 as part of the metal plug 84 below the implantation window 90 where ion implantation 92 was performed, as exemplarily shown in FIG. 5E. Annealing may be performed before or after removal of the lithographic hard mask 88.

The method may further comprise arranging an interconnection line at the resistive switching medium 94. In one example shown in FIGS. 5F to 5H, arranging the interconnection line, such as the interconnection line 48 described above, for example, may comprise depositing a dielectric trench isolation layer 96 on the surface 86 of the dielectric layer 68. The dielectric trench isolation layer 96 may comprise dielectric trench isolation material 12 as exemplarily described in connection with FIG. 1, above. Subsequently a trench etch mask 98 is formed on top of the dielectric trench isolation layer 96, and structured to form a trench etch window 100, as exemplarily shown in FIG. 5F.

As shown in FIG. 5G, the dielectric trench isolation layer 96 is removed in a region below the trench etch window 100 to form a trench 102, such as the exemplary trench 10 described in connection with FIGS. 1 to 3, above. Formation of the trench 102 may be achieved by etching, such as reactive ion etching, for example. In the example shown in FIG. 5G, formation of the trench 102 comprises uncovering the via opening 78 such that the resistive switching medium 94 is laid open for being electrically connected to the interconnection line to be formed in subsequent processes.

Accordingly, arranging the interconnection line may comprise depositing electrically conductive material in the trench 102 in contact with the resistive switching medium 94. As exemplarily shown in FIG. 5H, arranging the interconnection line may comprise filling the trench 102 with electrically conductive material, such as copper or other metal, for example. In the particular example of FIG. 5H, the electrically conductive interconnection line formed within the trench 102 comprises a seed layer 104 and a top contact 106 and it may be formed in accordance with the well-established Cu-dual-damascene technology, for example. Excess metal outside the trench 102 may be removed by chemical mechanical polishing (CMP), for example. In one example, the trench etch mask 98 is removed by chemical mechanical polishing together with the excess metal. In another example, the trench etch mask 98 is removed before deposition of the metal. The dielectric trench isolation layer 96 together with the interconnection line formed within the trench 102 form an interconnection layer, such as the interconnection layer 44 described above, for example. As shown in FIG. 5H, in a subsequent process a further dielectric layer 108, such as an inter-metal dielectric layer IMD exemplarily described in connection with FIG. 1 or the further dielectric layer 28′ as exemplarily described in connection with FIGS. 2 and 3 above, may be arranged on top of the interconnection layer and an electrically conductive via 110 may be formed in said dielectric layer 108 to electrically connect to the interconnection line, and particularly to the top contact 106.

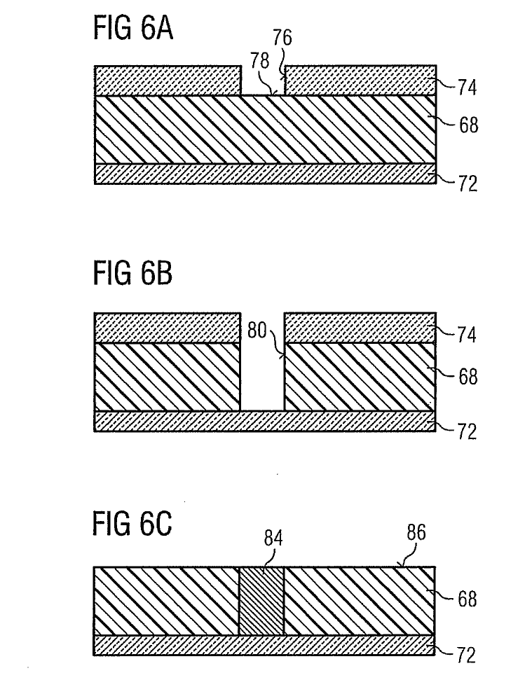

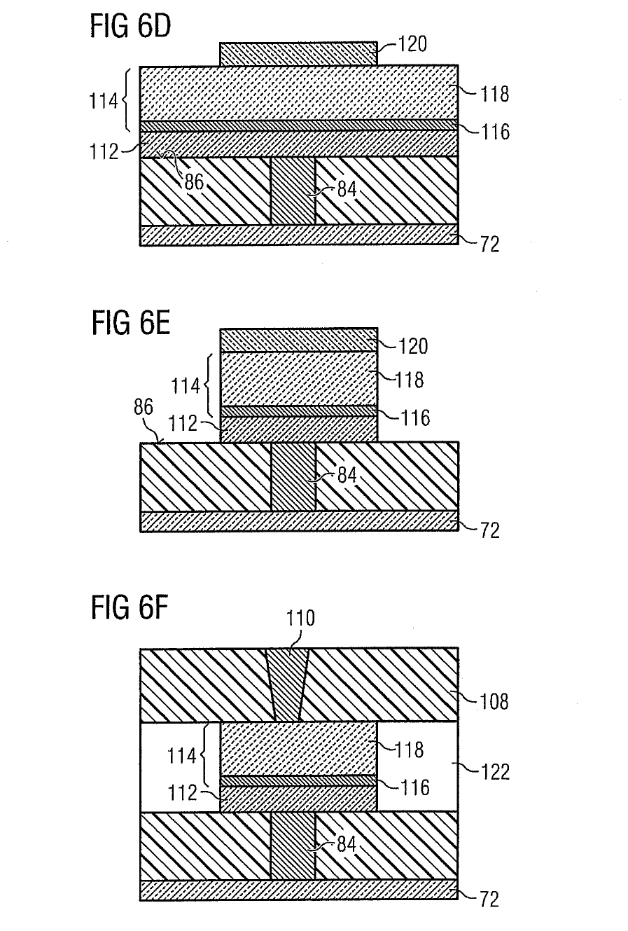

In another example, not shown in FIG. 5, arranging the interconnection line at the resistive switching medium 94 may be performed in a reverse order process, where deposition and structuring of the metal forming the interconnection line is performed before deposition of the trench isolation material 96, similar to the process order described in connection with FIGS. 6 in the following.

In a further aspect, another exemplary method of fabricating a memory device is described with reference to FIGS. 6A to 6F. According to the examples shown in FIGS. 6A to 6C, the method may comprise a step of creating a via conductor extending through a dielectric layer 68. Analogous features as in the previously describe examples of FIGS. 5A to 5C are indicated with the same reference numerals in FIGS. 6A to 6C. Accordingly, for a more detailed description of these features, reference is made to the description above. In the example shown in FIGS. 6A to 6C, the via hole 80 is formed with a single anisotropic etching process.

In a further process, exemplarily shown in FIG. 6D, starting from a structure having a surface 86 as shown in FIG. 6C, such as the sequence intermediate surface 32 described above, for example, a resistive switching medium 112 and an interconnection metal layer 114, exemplarily comprising a seed layer 116 and a top layer 118, may be deposited as a layered structure on top of the surface 86. The resistive switching medium 112 may comprise at least one of the group consisting of copper oxide and copper sulfide, such as CuS₂, for example. The seed layer 116 may comprise a copper seed layer and the top contact may comprise copper, for example. The interconnection metal layer 114 may be fabricated in accordance with a metal deposition in the well-established Cu-dual-damascene technology, for example.

Subsequently, a memory stack etch mask 120 may be deposited and structured on top of the interconnection metal layer 114. The memory stack etch mask 120 may serve as a hard mask for structuring of a memory stack by reactive ion etching of the not covered layer sequence, for example, as exemplarily shown in FIG. 6E.

In subsequent exemplary steps shown in FIG. 6F, a dielectric trench isolation layer 122 may be fabricated by chemical vapor deposition (CVD), for example, and subsequent chemical-mechanical polishing (CMP). After removal of the memory stack etch mask 120 and the excess isolation material from the top of the interconnection line 114, a further dielectric layer 108, such as an inter-metal dielectric layer IMD exemplarily described in connection with FIG. 1 or the further dielectric layer 28′ as exemplarily described in connection with FIGS. 2 and 3 above, may be arranged on top of the interconnection layer and an electrically conductive via 110 may be formed in said dielectric layer 108 to provide electrical connection to the interconnection line 114, and particularly to the top contact 118.

In another example, not shown in FIG. 6, arranging the interconnection line 114 at the resistive switching medium may be performed in a reverse order process, where deposition and structuring of the dielectric trench isolation layer 122 is performed before deposition of the resistive switching medium and the interconnection line material, similar to the process order described in connection with FIG. 5, above.

A number of examples and implementations have been described. Other examples and implementations may, in particular, comprise one or more of the above features. In one example a memory device, an integrated circuit, or an interconnection structure as exemplarily described above may be fabricated by one or more of the exemplary methods described herein. Nevertheless, it will be understood that various modifications may be made. Accordingly, other implementations are within the scope of the following claims.

What is claimed is:

1. A memory device comprising:
a vertically extending via conductor;
a lateral interconnection line; and
a storage region interposed between the via conductor and the interconnection line.

2. The memory device of claim 1, comprising:
a vertical-interconnection layer comprising a via hole which extends through the vertical-interconnection layer and which is at least partly filled with said via conductor; and
a lateral-interconnection layer arranged at the vertical-interconnection layer and comprising at least one lateral trench which is in communication with the via hole and which is at least partly filled with said interconnection line.

3. The memory device of claim 2, wherein the storage region comprises a resistive switchable medium.

4. The memory device of claim 3, wherein the storage region is arranged in the via hole.

5. The memory device of claim 3, wherein the storage region is arranged in the trench.

6. An integrated circuit comprising at least one layer sequence with
a dielectric layer having a via hole formed therein and
an interconnection layer having a trench formed therein, where the trench is in communication with the via hole such as to form an interconnection channel together with the via hole,
wherein a resistive switchable medium is arranged in said interconnection channel, where the resistive switchable medium forms an electrical interconnection between a via conductor arranged in the via hole and an interconnection line arranged in the trench.

7. The integrated circuit of claim 6, wherein the via conductor extends vertically and the interconnection line extends laterally.

8. The integrated circuit of claim 6, wherein the resistive switchable medium is arranged in the via hole.

9. The integrated circuit of claim 6, wherein the resistive switchable medium is arranged in the trench.

10. The integrated circuit of claim 6, having at least one memory cell that comprises said resistive switchable medium as a storage region.

11. An interconnection structure comprising at least one interconnection layer sequence which comprises:
a dielectric layer having a first sequence connection surface and a sequence intermediate surface; and
an interconnection layer arranged at the sequence intermediate surface and comprising a second sequence connection surface,
wherein in the interconnection layer sequence an interconnection channel is formed which comprises:
a via hole formed in the dielectric layer and extending from a first via opening in the first sequence connection surface to a second via opening in the sequence intermediate surface; and
a trench formed in the interconnection layer in communication with the via hole at the second via opening, wherein a resistive switchable medium arranged in the interconnection channel at the second via opening forms an electrical interconnection between a via conductor arranged in the via hole and an interconnection line arrange in the trench.

12. The interconnection structure of claim 11, wherein the dielectric layer comprises undoped silicate glass and/or fluorinated silicate glass.

13. The interconnection structure of claim 11, wherein the interconnection line comprises copper.

14. The interconnection structure of claim 13, wherein the interconnection line comprises a copper top contact and a copper seed layer arranged at least between the copper top contact and the resistive switchable medium.

15. The interconnection structure of claim 11, wherein the first sequence connection surface is substantially parallel to the second sequence connection surface.

16. A memory device comprising:
a semiconductor operation layer having an operation layer surface with at least one contact area;
a pre-metal dielectric layer arranged at the operation layer surface of the semiconductor operation layer, wherein the pre-metal dielectric layer has an interconnection surface and comprises a via hole which extends through the pre-metal dielectric layer from a via opening in the interconnection surface to the contact area and which is at least partly filled with a via conductor;
a structured metallization layer arranged at the interconnection surface of the pre-metal dielectric layer and comprising at least one trench which is in communication with the via hole and which is at least partly filled with an electrically conductive interconnection line; and
a resistive storage region comprising a resistive switchable medium which is arranged at the interconnection surface between the via conductor and the interconnection line.

17. The memory device of claim 16, wherein the resistive switchable medium comprises a transition metal chalcogenide or a transition metal oxide.

18. The memory device of claim 17, wherein the switchable medium comprises a transition metal material which is also comprised in at least one of the via conductor and the interconnection line.

19. The memory device of claim 16, wherein the via conductor comprises a tungsten plug.

20. The memory device of claim 19, wherein at least a portion of the resistive storage region is arranged within the via hole and comprises Tungsten oxide.

21. The memory device of claim 16, wherein the interconnection line comprises copper.

22. The memory device of claim 21, wherein at least a portion of the resistive storage region is arranged within the trench and comprises at least one of the group of copper sulfide and copper oxide.

23. The memory device of claim 16, wherein the interconnection surface is substantially planar.

24. The memory device of claim 16, wherein the contact area is a contact area of a source/drain region of a select transistor arranged in the semiconductor operation layer, and wherein the via conductor is electrically connected to said source/drain region at the contact area.

25. The memory device of claim 16, wherein the semiconductor operation layer comprises a plurality of select transistors arranged in at least one array comprising rows and columns;
wherein gate contacts of select transistors within the same row are electrically connected to each other through a common word line;
wherein the pre-metal dielectric layer comprises a plurality of via holes substantially arranged in said array, and wherein each via hole is at least partly filled with a via conductor being electrically connected to a source/drain region of one of the plurality of select transistors;
wherein the structured metallization layer comprises a plurality of substantially parallel trenches extending along the columns of said array, wherein each trench communicates with a plurality of via holes within the same column and is at least partly filled with an electrically conductive bit line; and
wherein the resistive memory device comprises a plurality of resistive storage regions, wherein each of the storage regions is arranged at a via opening between the respective via conductor and a bit line and is electrically connected to the respective via conductor and to said bit line.

26. A method of integrating a storage medium in an embedded system comprising:
creating a via conductor extending vertically through a dielectric layer;
arranging a resistive switchable medium at one end of the via conductor; and
arranging a laterally extending interconnection line at the resistive switchable medium.

27. The method of claim 26, wherein creating a via conductor comprises:
forming a via hole in the dielectric layer; and
filling the via hole with a transition metal plug,
wherein arranging a resistive switchable medium comprises implanting oxygen in at least part of the transition metal plug next to an interconnection surface of the dielectric layer.

28. The method of claim 27, wherein arranging an interconnection line comprises arranging the interconnection line at the interconnection surface of the dielectric layer.

29. The method of claim 27, wherein the transition metal plug comprises tungsten.

30. The method of claim 26, wherein the interconnection line comprises copper.

31. The method of claim 26, wherein creating a via conductor comprises:
forming a via hole in a dielectric layer; and
filling the via hole with a via conductor,
wherein arranging a resistive switchable medium comprises arranging said resistive switchable medium at an interconnection surface of the dielectric layer such as to electrically contact the via conductor; and
wherein arranging an interconnection line comprises at least partly covering the resistive switchable medium with said interconnection line.

32. The method of claim 31, wherein the resistive switchable medium comprises copper oxide or copper sulfide, and wherein the interconnection line comprises copper.

33. A method of fabricating a memory device, comprising:
arranging on a substrate surface having at least one contact area a pre-metal dielectric layer having an interconnection surface;
forming a via hole extending in the pre-metal dielectric from a via opening in the interconnection surface to the contact area;
filling the via hole at least partly with a via conductor;
arranging at the via opening in the interconnection surface a resistive switchable medium such that the resistive switchable medium electrically connects to the via conductor;
arranging at the interconnection surface a structured metallization layer comprising at least one interconnection line that electrically connects the resistive switchable medium.

34. The method of claim 33, wherein the step of forming the via hole comprises
depositing on the interconnection surface an etch mask defining an etch opening at the position of the via opening;
isotropically etching the pre-metal dielectric layer at the via opening to a first etch depth; and
anisotropically etching the pre-metal dielectric layer to extend the via hole to the contact area.

35. The method of claim 33, wherein filling the via hole comprises filling the via hole at least partly with a tungsten plug.

36. The method of claim 35, wherein the step of arranging the resistive switchable medium comprises a process of oxygen ion implantation into at least part of the tungsten plug.

37. The method of claim 33, wherein the via hole is filled with the via conductor up to the via opening in the interconnection surface;
wherein the method comprises a step of arranging at the interconnection surface a dielectric trench isolation layer defining at least one trench that communicates with the via opening;
wherein the step of arranging the resistive switchable medium comprises depositing the resistive switchable medium at least at the via opening in the trench; and
wherein the step of arranging the structured metallization layer comprises depositing electrically conductive material at least in the trench to from the at least one interconnection line.

38. The method of claim 33, wherein the step of arranging the structured metallization layer comprises depositing at the interconnection surface a copper seed layer and depositing on the copper seed layer a copper top contact.

39. The method of claim 33, wherein the step of filling the via hole at least partly with a via conductor comprises establishing at the contact area an electrical connection of the via conductor to a source/drain region of a select transistor.
